(19) United States
(12) Patent Application Publication
(10) Pub. No.: US 2015/0207097 A1
(43) Pub. Date: Jul. 23, 2015

(54) COMPONENTS AND METHOD FOR PRODUCING COMPONENTS

(71) Applicant: OSRAM OLED GmbH, Regensburg (DE)

(72) Inventors: Thilo Reusch, Regensburg (DE); Philipp Schwamb, Regensburg (DE)

(21) Appl. No.: 14/420,685

(22) PCT Filed: Aug. 8, 2013
(86) PCT No.: PCT/EP2013/066660

§ 371 Date: Feb. 10, 2015

(30) Foreign Application Priority Data
Aug. 10, 2012 (DE) 10 2012 214 248.7

(51) Int. Cl. H01L 51/52; H01L 51/00; H01L 51/50; H01L 51/56; H01L 51/44

(52) U.S. Cl. CPC H01L 51/5246; H01L 51/56; H01L 51/442; H01L 51/5206; H01L 51/5234; H01L 51/5012; H01L 51/5237; H01L 51/0096; H01L 51/448

(57) ABSTRACT

Various embodiments may relate to a component, including a carrier, a first electrode on or over the carrier, an organic functional layer structure on or over the first electrode, a second electrode on or over the organic functional layer structure, and thin film encapsulation. The first electrode and the second electrode are configured in such a way that an electrical connection of the first electrode to the second electrode is established only through the organic functional layer structure. The first electrode and/or the second electrode is electrically coupled to the carrier. The thin-film encapsulation together with the carrier forms a structure which seals the organic functional layer structure as well as at least one electrode out of the first electrode and the second electrode hermetically against water and/or oxygen.

### RELATED APPLICATIONS

The present application is a national stage entry according to 35 U.S.C. §371 of PCT application No.: PCT/EP2013/066660 filed on Aug. 8, 2013, which claims priority from German application No.: 10 2012 214 248.7 filed on Aug. 10, 2012, and is incorporated herein by reference in its entirety.

### TECHNICAL FIELD

In various configurations, components and a method for their production are provided.

### BACKGROUND

Components, for example organic optoelectronic components, for example organic light-emitting diodes (OLEDs) or organic solar cells, have a first electrode and a second electrode with an organic functional layer structure between them.

By the electrodes, in the case of an OLED, charge carriers are transported by contact tracks with high electrical conductance, for example metallic contact tracks, from a current supply into the organic functional layer structure.

The powering of OLEDs requires a uniform distribution of the current from the contact points at the edge of the OLED slab into the surface of the electrodes and into the surface of the component.

In the ideal case, the two-dimensional surfaces of the electrodes should have the same surface area as the two-dimensional surfaces of the organic functional layer structure.

Additional requirements of the electrodes may conflict with a configuration having a high electrical conductance.

For example, requirements for transparency of the electrodes and/or the process time cannot be satisfied with every material and with every thickness.

This can lead to a lower conductance often being achieved with the two-dimensional electrodes than is desirable, for example in order to achieve a uniform current distribution.

One conventional possibility of nevertheless distributing current uniformly in the surface is to introduce the current at a plurality of contact points distributed over the surface or—which is easier to carry out—the edges.

In order to limit the number of contact points, besides the active surface of an OLED, contact tracks are often required in order to distribute the current.

The contact tracks are conventionally applied on an inactive edge of the component.

In another conventional component, contact tracks are applied in the active surface (busbars) in order to transport the current from the component sides into its surface. In the absence of these contact tracks, the overall appearance of the component, or its size, may be impaired, for example by luminous surfaces with an inhomogeneous luminance or increased requirements for the conductance of the electrodes.

One conventional method of contacting the organic functional layer structure is to form contact tracks next to or in the active surface of the organic functional layer structure, i.e. the light-emitting or light-converting region, and to use transparent electrodes.

In another conventional method, an electrode insulated by encapsulation may be externally powered, i.e. electrically operated, by a contact through the encapsulation.

These methods can have the disadvantage that the protective effect of the encapsulation for the organic functional layer structure in respect of harmful substances is reduced, for example damaged.

Harmful substances, for example solvents, for example water; and/or oxygen, may potentially lead to degradation or ageing of organic substances, and therefore limit the operating life of organic components.

Organic substance, or organic layers, should therefore be protected against water and/or oxygen, and are therefore often encapsulated.

The contacts through the encapsulation, for example VIAs, however, represent potential weak points for diffusion flows in respect of water and/or oxygen in the encapsulation, and should therefore be avoided.

The requirement for transparent electrodes restricts the choice of substances for electrodes, as well as their layer thicknesses. The conductance is thereby limited, and the surface area of an OLED with homogeneous luminance is therefore limited. The contact tracks of an OLED may furthermore be visible to the naked eye and impair the overall esthetic appearance.

### SUMMARY

In various configurations, components and a method for their production are provided, with which it is possible to reduce the number of penetrations through the encapsulation and to distribute the current in the component surface.

In the scope of this description, an organic substance may be understood as a compound of carbon existing in chemically uniform form and distinguished by characteristic physical and chemical properties, regardless of the respective aggregate state. Furthermore, in the scope of this description, an inorganic substance may be understood as a compound without carbon, or a simple carbon compound, existing in chemically uniform form and distinguished by characteristic physical and chemical properties, regardless of the respective aggregate state. In the scope of this description, an organic-inorganic substance (hybrid substance) may be understood as a compound including compound parts which contain carbon and compound parts which are free of carbon, existing in chemically uniform form and distinguished by characteristic physical and chemical properties, regardless of the respective aggregate state. In the scope of this description, the term “substance” includes all substances mentioned above, for example an organic substance, an inorganic substance and/or a hybrid substance. Furthermore, in the scope of this description, a substance mixture may be understood as something that consists of constituents of two or more different substances, the constituents of which are for example very finely distributed. A substance class is to be understood as a substance or a substance mixture consisting of one or more organic substances, one or more inorganic substances or one or more hybrid substances. The term “material” may be used synonymously with the term “substance”.

In the scope of this description, a harmful environmental effect may be understood as any effects which may potentially lead to degradation or ageing of organic substances, and may therefore limit the operating life of organic components, for example a harmful substance, for example oxygen, and/or for example a solvent, for example water.

In the scope of this description, enclosure of a first layer by a second layer may be understood as the presence of a common interface of the first layer with the second layer in relation to the lateral interfaces of the first layer. In other words: the first layer and the second layer may have physical contact in relation to the lateral interfaces of the first layer.

The degree of physical contact, or the proportion of the common interface of the first layer with the second layer in relation to the size of the lateral interfaces of the first substrate, may determine the degree of enclosure, for example whether the second layer encloses the first layer partially or fully.

If the second layer encloses the side surfaces of the two-dimensional first layer, this may be understood as lateral enclosure. The side surfaces of the first layer may, for example, be the surfaces of the first layer which have the shortest length of the first layer. In addition, the first layer and the second layer may, for example, share together one of the two-dimensional interfaces of the first layer.

In various embodiments, a component is provided, the component including: a carrier; a first electrode on or over the carrier; an organic functional layer structure on or over the first electrode; a second electrode on or over the organic functional layer structure, wherein the first electrode and the second electrode are configured in such a way that an electrical connection of the first electrode to the second electrode is established only through the organic functional layer structure; and encapsulation; wherein the first electrode and/or the second electrode is electrically coupled to the carrier; and wherein the encapsulation together with the carrier forms a structure which seals the organic functional layer structure as well as at least one electrode out of the first electrode and the second electrode hermetically against water and/or oxygen.

In the scope of this description, a first electrode and a second electrode, which are connected to one another only by an organic functional layer structure, i.e. have no direct physical and electrical contact, may be understood as electrodes electrically insulated from one another.

In other words: the first electrode and the second electrode may be configured in such a way that the first electrode and the second electrode have no further electrical connection to one another other than through the organic functional layer structure, i.e. the optoelectronic component is configured in such a way that other than through the organic functional layer structure the two electrodes are electrically insulated from one another, for example have no physical contact with one another.

Hermetically sealed encapsulation may in this case be configured as continuous, without gaps, i.e. circumferential, direct or indirect connection of the encapsulation to the carrier.

A hermetically sealed layer may for example have a diffusion rate in relation to water and/or oxygen of less than approximately 10⁻¹ g/(m²d), a hermetically sealed cover and/or a hermetically sealed carrier may for example have a diffusion rate in relation to water and/or oxygen of less than approximately 10⁻⁴ g/(m²d), for example in a range of from approximately 10⁻⁴ g/(m²d) to approximately 10⁻¹⁰ g/(m²d) to in a range of from approximately 10⁻⁴ g/(m²d) to approximately 10⁻⁶ g/(m²d).

In various configurations, a substance which is hermetically sealed in relation to water, or a hermetically sealed substance mixture, may include or be formed from a ceramic, a metal and/or a metal oxide.

A direct connection may be configured as physical contact. An indirect connection may include further layers between the encapsulation and the carrier, these being however hermetically sealed per se against water and/or oxygen, for example including an insulation layer or the first electrode or the second electrode.

In one configuration, the carrier may include or be formed from a substance or a substance mixture from the group of substances: organic substance; inorganic substance, for example steel, aluminum, copper; or organic-inorganic hybrid substance, for example organically modified ceramic; for example an organic substance, for example a plastic, for example polyolefins (for example polyethylene (PE) with high or low density or polypropylene (PP)), polyvinyl chloride (PVC), polystyrene (PS), polyester, polycarbonate (PC), polyethylene terephthalate (PET), polyethersulfone (PES), polyethylene naphthalate (PEN), polymethyl methacrylate (PMMA), polyimide (PI), colorless polyimide (CPI), polyether ketones (PEEK).

In another configuration, the carrier may be configured to be flat.

In another configuration, the carrier may be configured to be flexible.

In another configuration, the carrier may be configured to be transparent.

In another configuration, the carrier may be configured to be electrically conductive.

In another configuration, the carrier may be configured as an intrinsic electrical conductor, for example as sheet metal or a thin foil of aluminum, copper, steel.

The intrinsically conductive substance may simultaneously have an intrinsic diffusion barrier against water and/or oxygen. This restricts the thickness of the carrier insofar as thin carriers, for example with a thickness of from approximately 10 nm to approximately 300 nm, cannot be formed, for example configured, reliably hermetically sealed from an organic and/or inorganic substance. The specific thickness is, however, dependent on the specific substance or substance mixture and dependent on the structure of the layer cross section of the carrier.

The carrier may include the same substance or the same substance mixture as the second electrode.

In another configuration, the carrier may include at least one electrically insulating region and at least one electrically conductive region.

The thickness of the at least one conductive region should be selected in such a way that it cannot be penetrated, or at most can be penetrated in very small amounts, by OLED-damaging substances such as water, oxygen or solvents. The specific thickness may, however, be dependent on the specific substance or substance mixture of the conductive region and dependent on the structure of the layer cross section of the carrier.

A conductive region may be provided, for example applied onto the carrier, when the carrier itself is not electrically conductive or the electrical conductivity of the carrier is insufficient, or the carrier is intended to be nonconductive. A nonconductive carrier may for example be used in order to insulate elements, for example conductive regions, on the carrier from the environment.

In the case of a plurality of electrically conductive regions of the carrier, which are not directly continuous, the first electrode may be electrically coupled to a different conductive region of the carrier than the second electrode.

In another configuration, the electrically conductive region may be configured as a conductor layer on the electrically insulating region, for example a nonconducting film, for example a plastic film having a conductive coating or conductor layer structure, for example copper, silver, aluminum, chromium, nickel or the like.

In order to apply the conductive coating, for example copper, an adhesion promoter, for example a layer of chromium, for example with a thickness of from approximately 1 nm to approximately 50 nm may be applied onto the nonconducting, i.e. insulating, region. Metallic layers may be applied onto the nonconducting region, for example, by vapor deposition or sputtering.

In another configuration, an insulation layer may be formed between the first electrode and the carrier.

The insulation layer may be configured as an electrical insulator, i.e. as an electrical insulation layer.

Furthermore, the insulation layer may be configured in order to reduce the surface roughness, for example of the carrier, i.e. for planarization.

Furthermore, the insulation layer may be configured in such a way that the layers over or on the insulation layer are hermetically sealed against harmful substances, for example water and/or oxygen.

In one configuration, the insulation layer may include or be formed from a substance or a substance mixture from the group of substances: organic substance; inorganic substance, for example an oxide compound, a nitride compound, and/or a product of a sol-gel process, for example a spin-on glass; or organic-inorganic hybrid substance, for example organically modified ceramic; for example an organic substance, for example a plastic, for example polyolefins (for example polyethylene (PE) with high or low density or polypropylene (PP)), polyvinyl chloride (PVC), polystyrene (PS), polyester, polycarbonate (PC), polyethylene terephthalate (PET), polyethersulfone (PES), polyethylene naphthalate (PEN), polymethyl methacrylate (PMMA), polyimide (PI), colorless polyimide (CPI), polyether ketones (PEEK), an epoxide, an acrylate, bitumen, a self-assembled monolayer (SAM), for example a silane compound or a thiol compound.

In one configuration, the insulation layer may have a thickness in a range of from approximately 0.1 nm to approximately 1 mm, for example in a range of from approximately 1 nm to approximately 100 μm.

An insulation layer with a thickness of approximately 0.1 nm may, for example, be formed by a self-assembled monolayer.

In one configuration, the insulation layer may include or be formed from an organic substance or an organic substance mixture and an inorganic substance or an inorganic substance mixture. In this way, for example, water which diffuses into the insulation layer can be contained, for example stored, in the organic part of the insulation layer.

The insulation layer may include or be formed from the same substance or a similar substance as the organic functional layer structure.

In other words: if an insulation layer with an electrically insulating effect in relation to the carrier is optional, the first electrode may be fully enclosed by the organic functional layer structure.

The insulation layer may in this case be configured in order to planarize the carrier and/or in order to electrically insulate the carrier and the first electrode.

In another configuration, the insulation layer may be configured to be transparent or translucent.

In another configuration, the insulation layer may at least partially enclose the first electrode in such a way that the insulation layer forms lateral electrical insulation between the first electrode and the second electrode, and the first electrode has electrical coupling to the organic functional layer structure.

In another configuration, the first electrode may be configured to be transparent.

In another configuration, the organic functional layer structure may be configured to be transparent.

In another configuration, the second electrode may be configured to be transparent.

In another configuration, the encapsulation may be configured to be transparent.

In another configuration, the organic functional layer structure may enclose the first electrode in such a way that the organic functional layer structure physically isolates the first electrode laterally from the second electrode.

In another configuration, the encapsulation may enclose with the carrier a plurality of layer structures in such a way that the individual layer structures include the layers: an insulation layer, a first electrode, an organic functional layer structure; and a second electrode.

The insulation layer may in this case be optional, however, depending on the specific configuration of the carrier, for example when the first electrode is applied in physical contact with the carrier or the carrier or a region of the carrier is configured as a first electrode, i.e. a first electrode may coincide with the conductive carrier.

In another configuration, the plurality of layer structures may be configured in such a way that the various layer structures have a common first electrode and/or a common second electrode.

In another configuration the common first electrode and/or the common second electrode of the plurality of layer structures may have an electrical contact with the common carrier between the plurality of layer structures.

In another configuration, the various layer structures may be arranged next to one another.

In another configuration, the various layer structures may be arranged above one another.

In another configuration, the electrical coupling of the first electrode to the carrier or the electrical coupling of the second electrode to the carrier may include a through-contact.

In another configuration, the first electrode may be configured in such a way that the first electrode is electrically coupled to the carrier and the first electrode at least partially encloses the insulation layer laterally.

In another configuration, the second electrode may be configured in such a way that the second electrode is electrically coupled to the carrier and the second electrode at least partially encloses the organic functional layer structure, or the organic functional layer structure and the insulation layer.

In another configuration, the component may be configured as an optoelectronic component, preferably as an organic light-emitting diode or as an organic solar cell.

In various embodiments, a method for producing a component is provided, the method including: formation of a first electrode over or on a carrier; formation of an organic functional layer structure over or on the first electrode; formation of a second electrode over or on the organic functional layer structure; wherein the first electrode and the second electrode are configured in such a way that an electrical connection of the first electrode to the second electrode is established only through the organic functional layer structure; and formation of encapsulation; wherein the encapsulation together with the carrier forms a structure which seals the organically functional layer structure as well as at least one electrode out of the first electrode and the second electrode hermetically against water and/or oxygen.

In one configuration of the method, the carrier may include or be formed from a substance or a substance mixture from the group of substances: organic substance; inorganic substance; or organic-inorganic hybrid substance.

In another configuration of the method, the carrier may be configured to be flat.

In another configuration of the method, the carrier may be configured to be flexible.

In another configuration of the method, the carrier may be configured to be transparent.

In another configuration of the method, the carrier may be configured to be electrically conductive.

In another configuration of the method, the carrier may be configured as an intrinsic electrical conductor.

In one configuration of the method, the carrier may include at least one electrically insulating region and at least one electrically conductive region.

In another configuration of the method, the electrically conductive region may be configured as a conductor layer on the electrically insulating region.

In another configuration of the method, an insulation layer may be applied on or over the carrier before the first electrode is applied on the carrier.

In another configuration of the method, an insulation layer may be formed between the first electrode and the carrier.

The insulation layer may for example be configured as an electrical insulator, i.e. as an electrical insulation layer.

Furthermore, the insulation layer may be configured in order to reduce the surface roughness, for example of the carrier, i.e. for planarization.

An insulation layer may additionally be configured in such a way that the layers over or on the insulation layer are hermetically sealed against harmful substances, for example water and/or oxygen.

In one configuration of the method, the insulation layer may include or be formed from a substance or a substance mixture from the group of substances: organic substances; inorganic substance, for example an oxide compound, a nitride compound, and/or a product of a sol-gel process, for example a spin-on glass; or organic-inorganic hybrid substance, for example organically modified ceramic; for example an organic substance, for example a plastic, for example polyolefins (for example polyethylene (PE) with high or low density or polypropylene (PP)), polyvinyl chloride (PVC), polystyrene (PS), polyester, polycarbonate (PC), polyethylene terephthalate (PET), polyethersulfone (PES), polyethylene naphthalate (PEN), polymethyl methacrylate (PMMA), polyimide (PI), colorless polyimide (CPI), polyether ketones (PEEK), an epoxide, an acrylate, bitumen, a self-assembled monolayer (SAM), for example a silane compound or a thiol compound.

In one configuration of the method, the insulation layer may have a thickness in a range of from approximately 0.1 nm to approximately 1 mm, for example in a range of from approximately 1 nm to approximately 100 μm.

An insulation layer with a thickness of approximately 0.1 nm may, for example, be formed by a self-assembled monolayer.

In one configuration of the method, the insulation layer may include or be formed from an organic substance or an organic substance mixture and an inorganic substance or an inorganic substance mixture.

In this way, for example, water which diffuses into the insulation layer can be contained, for example stored, in the organic part of the insulation layer.

In one configuration of the method, the insulation layer may be formed by a printing method and/or a coating method, for example by doctor blading, spraying, flexographic printing, template printing, screen printing, curtain coating, dip coating, spin coating, slot nozzle coating, a physical and/or chemical vapor deposition method, an atomic layer deposition method and/or a molecular layer deposition method.

In another configuration of the method, the insulation layer may be configured to be transparent or translucent.

In another configuration of the method, the insulation layer may be applied in such a way that the insulation layer encloses the first electrode in such a way that the insulation layer forms lateral electrical insulation between the first electrode and the second electrode, and the first electrode has electrical coupling to the organic functional layer structure.

In another configuration of the method, the first electrode may be configured to be transparent.

In another configuration of the method, the organic functional layer structure may be configured to be transparent.

In another configuration of the method, the second electrode may be configured to be transparent.

In another configuration of the method, the encapsulation may be configured to be transparent.

In another configuration of the method, the organic functional layer structure may be applied in such a way that the organic functional layer structure encloses the first electrode in such a way that the organic functional layer structure physically isolates the first electrode laterally from the second electrode.

In another configuration of the method, the encapsulation may be formed on or over the carrier in such a way that the encapsulation encloses a plurality of layer structures on a common carrier, wherein the individual layer structures include the layers: an insulation layer; a first electrode; an organic functional layer structure; and a second electrode.

In another configuration of the method, the various layer structures may be applied in such a way that the various layer structures have a common first electrode and/or a common second electrode.

In another configuration of the method, the various layer structures may be arranged next to one another.

In another configuration of the method, the various layer structures may be arranged above one another.

In another configuration of the method, the electrical coupling of the first electrode to the carrier or the electrical coupling of the second electrode to the carrier may be configured as a VIA connection, for example a contact through the insulation layer.

In another configuration of the method, the first electrode may be applied in such a way that the first electrode is electrically coupled to the carrier and the first electrode laterally encloses the insulation layer.

In another configuration of the method, the second electrode may be applied in such a way that the second electrode is electrically coupled to the carrier and the second electrode encloses the organic functional layer structure, or the organic functional layer structure and the insulation layer.

In one configuration of the method, the component may be produced as an optoelectronic component, preferably as an organic light-emitting diode or as an organic solar cell.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the disclosed embodiments. In the following description, various embodiments described with reference to the following drawings, in which:

FIG. 1 shows a schematic cross-sectional view of an optoelectronic component according to various embodiments;

FIG. 2 shows a schematic cross-sectional view of an optoelectronic component according to various embodiments;

FIG. 3 shows a schematic cross-sectional view of an optoelectronic component according to various embodiments;

FIG. 4 shows a schematic cross-sectional view of an optoelectronic component according to various embodiments;

FIG. 5 shows a schematic cross-sectional view of an optoelectronic component according to various embodiments;

FIG. 6 shows a schematic cross-sectional view of an optoelectronic component according to various embodiments;

FIG. 7 shows a schematic cross-sectional view of two optoelectronic components according to various embodiments; and

FIG. 8 shows a schematic plan view of an optoelectronic component according to various embodiments.

### DETAILED DESCRIPTION

In the following detailed description, reference will be made to the appended drawings, which are part of this description and in which specific embodiments in which the disclosure may be implemented are shown for illustration. In this regard, direction terminology such as “up”, “down”, “forward”, “backward”, “front”, “rear”, etc. is used with reference to the orientation of the figure or figures being described. Since components of embodiments can be positioned in a number of different orientations, the direction terminology is used for illustration and is in no way restrictive. It is to be understood that other embodiments may be used and structural or logical modifications may be carried out, without departing from the protective scope of the present disclosure. It is to be understood that the features of the various embodiments described herein may be combined with one another, unless specifically indicated otherwise. The following detailed description is therefore not to be interpreted in a restrictive sense, and the protective scope of the present disclosure is defined by the appended claims.

In the scope of this description, terms such as “connected” or “coupled” are used to describe both direct and indirect connection, and direct or indirect coupling. In the figures, elements which are identical or similar are provided with identical references, insofar as this is expedient.

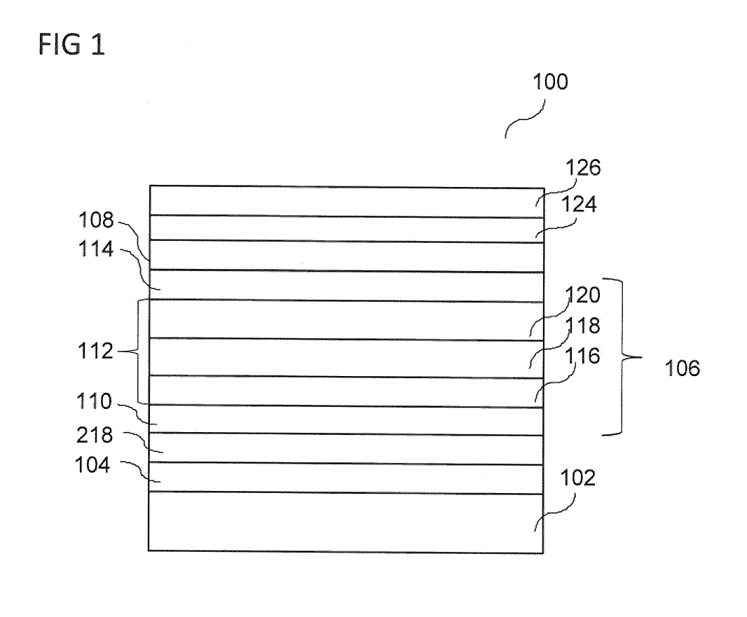

FIG. 1 shows a schematic cross-sectional view of an optoelectronic component according to various embodiments.

The light-emitting component 100 in the form of an organic light-emitting diode 100 may include a carrier 102.

The carrier 102 may for example be used as a carrier element for electronic elements or layers, for example light-emitting elements. For example, the carrier 102 may include or be formed from glass, quartz and/or a semiconductor material, or any other suitable material, for example steel, aluminum, copper.

The carrier 102 may furthermore include or be formed from a plastic film or a laminate including one or more plastic films. The plastic may for example include or be formed from one or more polyolefins (for example polyethylene (PE) with high or low density or polypropylene (PP)). The plastic may furthermore include or be formed from polyvinyl chloride (PVC), polystyrene (PS), polyester and/or polycarbonate (PC), polyethylene terephthalate (PET), polyimide (PI), polyethersulfone (PES) and/or polyethylene naphthalate (PEN), colorless polyimide (CPI), polymethyl methacrylate (PMMA), polyimide (PI), polyether ketones (PEEK).

The carrier 102 may include one or more of the materials mentioned above.

The carrier 102 may be configured to be translucent or even transparent.

In various embodiments, the term “translucent” or “translucent layer” may be understood as meaning that a layer is transmissive for light, for example for the light generated by the light-emitting component, for example of one or more wavelength ranges, for example for light in a wavelength range of visible light (for example at least in a subrange of the wavelength range of from 380 nm to 780 nm). For example, in various embodiments, the term “translucent layer” is to be understood as meaning that essentially the total amount of light input into a structure (for example a layer) is also output from the structure (for example layer), in which case a part of the light may be scattered.

In various embodiments, the term “transparent” or “transparent layer” may be understood as meaning that a layer is transmissive for light (for example at least in a subrange of the wavelength range of from 380 nm to 780 nm), light input into a structure (for example a layer) also being output from the structure (for example layer) essentially without scattering or light conversion. In various embodiments, “transparent” is therefore to be regarded as a special case of “translucent”.

For the case in which, for example, a light-emitting electronic component which is monochromatic or limited in its emission spectrum is intended to be provided, it is sufficient for the optically translucent layer structure to be translucent at least in a subrange of the wavelength range of the desired monochromatic light, or for the limited emission spectrum.

In various embodiments, the organic light-emitting diode 100 (or the light-emitting components according to the embodiments described above or below) may be configured as a so-called top and bottom emitter. A top and bottom emitter may also be referred to as an optically transparent component, for example a transparent organic light-emitting diode.

In various embodiments, a barrier thin film 104 may optionally be arranged on or over the carrier 102. The barrier thin film 104 may include or consist of one or more of the following materials: aluminum oxide, zinc oxide, zirconium oxide, titanium oxide, hafnium oxide, tantalum oxide, lanthanum oxide, silicon oxide, silicon nitride, silicon oxynitride, indium tin oxide, indium zinc oxide, aluminum-doped zinc oxide, and mixtures and alloys thereof. Furthermore, in various embodiments, the barrier thin film 104 may have a layer thickness in a range of from approximately 0.1 nm (one atomic layer) to approximately 5000 nm, for example a layer thickness in a range of from approximately 10 nm to approximately 200 nm, for example a layer thickness of approximately 40 nm.

An insulation layer 218 may be arranged on or over the barrier thin film 104.

In one configuration, the barrier thin film 104 may be configured as a part of an insulation layer 218 or as an insulation layer 218.

In other words: the barrier thin film 104 may in some configurations be the same as the insulation layer 218.

The insulation layer 218 may be configured as an electrical insulator, i.e. as an electrical insulation layer.

Furthermore, the insulation layer 218 may be configured in order to reduce the surface roughness, for example of the carrier, i.e. for planarization.

Furthermore, the insulation layer 218 may be configured in such a way that the layers over or on the insulation layer 218 are hermetically sealed against harmful substances, for example water and/or oxygen.

In one configuration, the insulation layer 218 may include or be formed from a substance or a substance mixture from the group of substances: organic substance; inorganic substance, for example an oxide compound, a nitride compound, and/or a product of a sol-gel process, for example a spin-on glass; or organic-inorganic hybrid substance, for example organically modified ceramic; for example an organic substance, for example a plastic, for example polyolefins (for example polyethylene (PE) with high or low density or polypropylene (PP)), polyvinyl chloride (PVC), polystyrene (PS), polyester, polycarbonate (PC), polyethylene terephthalate (PET), polyethersulfone (PES), polyethylene naphthalate (PEN), polymethyl methacrylate (PMMA), polyimide (PI), colorless polyimide (CPI), polyether ketones (PEEK), an epoxide, an acrylate, bitumen, a self-assembled monolayer (SAM), for example a silane compound or a thiol compound.

In one configuration, the insulation layer 218 may have a thickness in a range of from approximately 0.1 nm to approximately 1 mm, for example in a range of from approximately 1 nm to approximately 100 μm.

An insulation layer 218 with a thickness of approximately 0.1 nm may, for example, be formed by a self-assembled monolayer.

In one configuration of the, the insulation layer 218 may be formed by a printing method and/or a coating method, for example by doctor blading, spraying, flexographic printing, template printing, screen printing, curtain coating, dip coating, spin coating, slot nozzle coating, a physical and/or chemical vapor deposition method, an atomic layer deposition method and/or a molecular layer deposition method.

In one configuration, the insulation layer 218 may include or be formed from an organic substance or an organic substance mixture and an inorganic substance or an inorganic substance mixture. In this way, for example, water which diffuses into the insulation layer 218 can be contained, for example stored, in the organic part of the insulation layer 218.

An electrically active region 106 of the light-emitting component 100 may be arranged on or over the insulation layer 218. The electrically active region 106 may be understood as the region of the light-emitting component 100 in that an electric current for operation of the light-emitting component 100 flows. In various embodiments, the electrically active region 106 may include a first electrode 110, a second electrode 114 and an organic functional layer structure 112, as will be explained in more detail below.

Thus, in various embodiments, the first electrode 110 (for example in the form of a first electrode layer 110) may be applied on or over the insulation layer 218 (or, if the insulation layer 218 is absent or is the same as the barrier thin film 104, on or over the barrier thin film 104; or if the barrier thin film 104 is absent, on or over the carrier 102). The first electrode 110 (also referred to below as the lower electrode 110) may be formed from an electrically conductive material, for example a metal or a transparent conductive oxide (TCO), or a layer stack of a plurality of layers of the same metal or different metals and/or of the same TCO or different TCOs. Transparent conductive oxides are transparent conductive materials, for example metal oxides, for example zinc oxide, tin oxide, cadmium oxide, titanium oxide, indium oxide or indium tin oxide (ITO). Besides binary metal-oxygen compounds, for example ZnO, SnO₂, or In₂O₃, ternary metal-oxygen compounds, for example AlZnO, Zn₂SnO₄, CdSnO₃, ZnSnO₃, MgIn₂O₄, GaInO₃, Zn₂In₂O₅ or In₄Sn₃O₁₂ or mixtures of various transparent conductive oxides also belong to the TCO group and may be used in various embodiments. Furthermore, the TCOs do not necessarily correspond to a stoichiometric composition, and may furthermore be p-doped or n-doped.

In various embodiments, the first electrode 110 may include a metal; for example Ag, Pt, Au, Mg, Al, Ba, In, Ag, Au, Mg, Ca, Sm, Cu, Cr or Li, as well as compounds, combinations or alloys of these materials.

In various embodiments, the first electrode 110 may be formed from a layer stack of a combination of a layer of a metal on a layer of a TCO, or vice versa. One example is a silver layer, which is applied on an indium tin oxide layer (ITO) (Ag on ITO) or ITO/Ag/ITO multilayers.

In various embodiments, the first electrode 110 may provide one or more of the following materials as an alternative or in addition to the materials mentioned above: networks of metal nanowires and nanoparticles, for example of Ag; networks of carbon nanotubes; graphene particles and graphene layers; networks of semiconducting nanowires.

Furthermore, the first electrode 110 may include electrically conductive polymers or transition metal oxides or electrically conductive transparent oxides.

In various embodiments, the first electrode 110 and the carrier 102 may be configured to be translucent or transparent. In the case in which the first electrode 110 is formed from a metal, the first electrode 110 may for example have a layer thickness less than or equal to approximately 25 nm, for example a layer thickness less than or equal to approximately 20 nm, for example a layer thickness less than or equal to approximately 18 nm. Furthermore, the first electrode 110 may for example have a layer thickness greater than or equal to approximately 10 nm, for example a layer thickness greater than or equal to approximately 15 nm. In various embodiments, the first electrode 110 may have a layer thickness in a range of from approximately 10 nm to approximately 25 nm, for example a layer thickness in a range of from approximately 10 nm to approximately 18 nm, for example a layer thickness in a range of from approximately 15 nm to approximately 18 nm.

Furthermore, for the case in which the first electrode 110 is formed from a transparent conductive oxide (TCO), the first electrode 110 may for example have a layer thickness in a range of from approximately 50 nm to approximately 500 nm, for example a layer thickness in a range of from approximately 75 nm to approximately 250 nm, for example a layer thickness in a range of from approximately 100 nm to approximately 150 nm.

Furthermore, for the case in which the first electrode 110 is formed for example from a network of metal nanowires, for example of Ag, which may be combined with conductive polymers, a network of carbon nanotubes, which may be combined with conductive polymers, or of graphene layers and composites, the first electrode 110 may for example have a layer thickness in a range of from approximately 1 nm to approximately 500 nm, for example a layer thickness in a range of from approximately 10 nm to approximately 400 nm, for example a layer thickness in a range of from approximately 40 nm to approximately 250 nm.

The first electrode 110 may be configured as an anode, i.e. as a hole-injecting electrode, or as a cathode, i.e. as an electron-injecting electrode.

The first electrode 110 may include a first electrical terminal, to which a first electrical potential (provided by an energy source (not represented), for example a current source or a voltage source) can be applied. As an alternative, the first electrical potential may be applied to the carrier 102 and then delivered indirectly via the latter to the first electrode 110. The first electrical potential may, for example, be the ground potential or another predetermined reference potential.

Furthermore, the electrically active region 106 of the light-emitting component 100 may include an organic electroluminescent layer structure 112, which is applied on or over the first electrode 110.

The organic electroluminescent layer structure 112 may contain one or more emitter layers 118, for example including fluorescent and/or phosphorescent emitters, as well as one or more hole conduction layers 120 (also referred to as hole transport layer or layers 120). In various embodiments, as an alternative or in addition, one or more electron conduction layers 116 (also referred to as electron transport layer or layers 116) may be provided.

In one configuration, the order of the layers of the electrically active region 106 may be reversed. In other words: the second electrode 114 may be applied on or over the (optional) insulation layer 218, one or more hole conduction layers 120 may be applied on or over the second electrode 114, one or more emitter layers 118 may be applied on or over the one or more hole conduction layers 120, one or more electron transport layers 116 may be applied on or over the one or more emitter layers 118, and thin-film encapsulation 108 may be applied on or over the one or more electron transport layers 116.

Examples of emitter materials which may be used in the light-emitting component 100 according to various embodiments for the emitter layer or layers 118 include organic or organometallic compounds, for example derivatives of polyfluorene, polythiophene and polyphenylene (for example 2- or 2,5-substituted poly-p-phenylene vinylene) and metal complexes, for example iridium complexes, for example blue phosphorescent FIrPic (bis(3,5-difluoro-2-(2-pyridyl)phenyl-(2-carboxypyridyl)-iridium III), green phosphorescent Ir(ppy)₃ (tris(2-phenylpyridine) iridium III), red phosphorescent Ru(dtb-bpy)₃*2(PF₆) (tris[4,4′-di-tert-butyl-(2,2′)-bipyridine]ruthenium(III) complex) and blue fluorescent DPAVBi (4,4-bis[4-(di-p-tolylamino)styryl]biphenyl), green fluorescent TTPA (9, 10-bis[N,N-di-(p-tolyl)-amino]anthracene) and red fluorescent DCM2 (4-dicyanomethylene)-2-methyl-6-julolidyl-9-enyl-4H-pyrane) as nonpolymeric emitters. Such nonpolymeric emitters may, for example, be deposited by thermal evaporation. Furthermore, polymeric emitters may be used, which may in particular be deposited by a wet chemical method, for example spin coating method.

The emitter materials may be embedded in a suitable way in a matrix material.

It should be pointed out that other suitable emitter materials are likewise provided in other embodiments.

The emitter materials of the emitter layer or layers 118 of the light-emitting component 100 may, for example, be selected in such a way that the light-emitting component 100 emits white light. The emitter layer or layers 118 may include a plurality of emitter materials emitting different colors (for example blue and yellow or blue, green and red); as an alternative, the emitter layer or layers 118 may also be constructed from a plurality of sublayers, for example a blue fluorescent emitter layer 118 or blue phosphorescent emitter layer 118, a green phosphorescent emitter layer 118 and a red phosphorescent emitter layer 118. Mixing of the different colors can lead to the emission of light with a white color impression. As an alternative, a converter material may also be arranged in the beam path of the primary emission generated by these layers, which material at least partially absorbs the primary radiation and emits secondary radiation with a different wavelength, so that a white color impression is obtained from (not yet white) primary radiation by the combination of primary and secondary radiation.

The organic electroluminescent layer structure 112 may in general include one or more electroluminescent layers. The one or more electroluminescent layers may include organic polymers, organic oligomers, organic monomers, nonpolymeric organic small molecules, or a combination of these materials. For example, the organic electroluminescent layer structure 112 may include one or more electroluminescent layers which is or are configured as a hole transport layer 120, so that, for example in the case of an OLED, effective hole injection into an electroluminescent layer or an electroluminescent region is made possible. As an alternative, in various embodiments, the organic electroluminescent layer structure 112 may include one or more functional layers which is or are configured as an electron transport layer 116, so that, for example in the case of an OLED, effective electron injection into an electroluminescent layer or an electroluminescent region is made possible. For example, tertiary amines, carbazole derivatives, conductive polyaniline or polyethylene dioxythiophene may be used as a material for the hole transport layer 120. In various embodiments, the one or more electroluminescent layers may be configured as an electroluminescent layer.

In various embodiments, the hole transport layer 120 may be applied, for example deposited, on or over the first electrode 110, and the emitter layer 118 may be applied, for example deposited, on or over the hole transport layer 120. In various embodiments, an electron transport layer 116 may be applied, for example deposited, on or over the emitter layer 118.

In various embodiments, the organic electroluminescent layer structure 112 (i.e. for example the sum of the thicknesses of hole transport layer or layers 120 and emitter layer or layers 118 and electron transport layer or layers 116) may have a layer thickness of at most approximately 1.5 μm, for example a layer thickness of at most approximately 1.2 μm, for example a layer thickness of at most approximately 1 μm, for example a layer thickness of at most approximately 800 nm, for example a layer thickness of at most approximately 500 nm, for example a layer thickness of at most approximately 400 nm, for example a layer thickness of at most approximately 300 nm. In various embodiments, the organic electroluminescent layer structure 112 may for example include a stack of a plurality of organic light-emitting diodes (OLEDs) that are arranged directly above one another, in which case each OLED may for example have a layer thickness of at most approximately 1.5 μm, for example a layer thickness of at most approximately 1.2 μm, for example a layer thickness of at most approximately 1 μm, for example a layer thickness of at most approximately 800 nm, for example a layer thickness of at most approximately 500 nm, for example a layer thickness of at most approximately 400 nm, for example a layer thickness of at most approximately 300 nm. In various embodiments, the organic electroluminescent layer structure 112 may for example include a stack of two, three or four OLEDs that are arranged directly above one another, in which case, for example, the organic electroluminescent layer structure 112 may for example have a layer thickness of at most approximately 3 μm.

The light-emitting component 100 may in general optionally include further organic functional layers, for example arranged on or over the one or more emitter layers 118 or on or over the electron transport layer or layers 116, which are used to further improve the functionality and therefore the efficiency of the light-emitting component 100.

The second electrode 114 (for example in the form of a second electrode layer 114) may be applied on or over the organic electroluminescent layer structure 110, or optionally on or over the one or more further organic functional layers.

In various embodiments, the second electrode 114 may include or be formed from the same materials as the first electrode 110, metals being particularly suitable in various embodiments.

In various embodiments, the second electrode 114 (for example for the case of a metallic second electrode 114) may for example have a layer thickness less than or equal to approximately 50 nm, for example a layer thickness less than or equal to approximately 45 nm, for example a layer thickness less than or equal to approximately 40 nm, for example a layer thickness less than or equal to approximately 35 nm, for example a layer thickness less than or equal to approximately 30 nm, for example a layer thickness less than or equal to approximately 25 nm, for example a layer thickness less than or equal to approximately 20 nm, for example a layer thickness less than or equal to approximately 15 nm, for example a layer thickness less than or equal to approximately 10 nm.

The second electrode 114 may in general be configured in a similar way to the first electrode 110, or differently thereto. The second electrode 114 may, in various embodiments, be formed from one or more of the materials and with the respective layer thickness described above in connection with the first electrode 110. In various embodiments, the first electrode 110 and the second electrode 114 are both configured to be translucent or transparent. The light-emitting component 100 represented in FIG. 1 may therefore be configured as a top and bottom emitter (expressed in another way, as a transparent light-emitting component 100).

The second electrode 114 may be configured as an anode, i.e. as a hole-injecting electrode, or as a cathode, i.e. as an electron-injecting electrode.

The second electrode 114 may include a second electrical terminal, to which a second electrical potential (which is different to the first electrical potential) provided by the energy source can be applied. The second electrical potential may, for example, have a value such that the difference from the first electrical potential has a value in a range of from approximately 1.5 V to approximately 20 V, for example a value in a range of from approximately 2.5 V to approximately 15 V, for example a value in a range of from approximately 3 V to approximately 12 V.

Encapsulation 108, for example in the form of thin-film encapsulation 108, may optionally also be formed on or over the second electrode 114, and therefore on or over the electrically active region 106.

In various embodiments, hermetically sealed encapsulation may include a cover and/or thin-film encapsulation.

In the scope of this application, “thin-film encapsulation” 108 may, for example, be understood as a layer or a layer structure which is suitable for forming a barrier against chemical contaminants or atmospheric substances, in particular against water (moisture) and oxygen. In other words, the thin-film encapsulation 108 is configured in such a way that it cannot be penetrated, or can be penetrated at most in very small amounts, by substances that damage OLEDs, such as water, oxygen or solvents.

According to one configuration, the thin-film encapsulation 108 may be configured as an individual layer (expressed another way, as a single layer). According to an alternative configuration, the thin-film encapsulation 108 may include a multiplicity of sublayers arranged on top of one another. In other words, according to one configuration, the thin-film encapsulation 108 may be configured as a layer stack. The thin-film encapsulation 108, or one or more sublayers of the thin-film encapsulation 108, may for example be formed by a suitable deposition method, for example by an atomic layer deposition (ALD) method according to one configuration, for example a plasma-enhanced atomic layer deposition (PEALD) method or a plasma-less atomic layer deposition (PLALD) method, or by a chemical vapor deposition (CVD) method according to another configuration, for example a plasma-enhanced chemical vapor deposition (PECVD) method or a plasma-less chemical vapor deposition (PLCVD) method, or alternatively by other suitable deposition methods.

By using an atomic layer deposition (ALD) method, very thin layers can be deposited. In particular, layers whose layer thicknesses lie in the atomic layer range can be deposited.

According to one configuration, in the case of thin-film encapsulation 108 which includes a plurality of sublayers, all the sublayers may be formed by an atomic layer deposition method. A layer sequence which only includes ALD layers may also be referred to as a “nanolaminate”.

According to an alternative configuration, in the case of thin-film encapsulation 108 which includes a plurality of sublayers, one or more sublayers of the thin-film encapsulation 108 may be deposited by a deposition method other than an atomic layer deposition method, for example by a vapor deposition method.

The thin-film encapsulation 108 may, according to one configuration, have a layer thickness of from approximately 0.1 nm (one atomic layer) to approximately 1000 nm, for example a layer thickness of from approximately 10 nm to approximately 100 nm according to one configuration, for example approximately 40 nm according to one configuration.

According to one configuration, in which the thin-film encapsulation 108 includes a plurality of sublayers, all the sublayers may have the same layer thickness. According to another configuration, the individual sublayers of the thin-film encapsulation 108 may have different layer thicknesses. In other words, at least one of the sublayers may have a different layer thickness than one or more others of the sublayers.

The thin-film encapsulation 108, or the individual sublayers of the thin-film encapsulation 108, may according to one configuration be configured as a translucent or transparent layer. In other words, the thin-film encapsulation 108 (or the individual sublayers of the thin-film encapsulation 108) may consist of a translucent or transparent material (or a material combination which is translucent or transparent).

According to one configuration, the thin-film encapsulation 108, or (in the case of a layer stack including a multiplicity of sublayers) one or more of the sublayers of the thin-film encapsulation 108, may include or consist of one of the following materials: aluminum oxide, zinc oxide, zirconium oxide, titanium oxide, hafnium oxide, tantalum oxide, lanthanum oxide, silicon oxide, silicon nitride, silicon oxynitride, indium tin oxide, indium zinc oxide, aluminum-doped zinc oxide, and mixtures and alloys thereof. In various embodiments, the thin-film encapsulation 108, or (in the case of a layer stack including a multiplicity of sublayers) one or more of the sublayers of the thin-film encapsulation 108, may include one or more high-index materials, or expressed another way one or more materials having a high refractive index, for example having a refractive index of at least 2.

In various embodiments, an adhesive and/or a protective coating 124 may be provided on or over the encapsulation 108, by which, for example, a cover 126 (for example a glass cover 126, plastic cover 126, metal cover 126) is fastened, for example adhesively bonded, on the encapsulation 108. In various embodiments, the optically translucent layer of adhesive and/or protective coating 124 may have a layer thickness of more than 1 μm, for example a layer thickness of up to approximately 1000 μm. In various embodiments, the adhesive may include or be a lamination adhesive.

In various embodiments, light-scattering particles, which can lead to a further improvement of the hue distortion and of the output efficiency, may also be embedded in the layer of adhesive (also referred to as the adhesive layer). In various embodiments, dielectric scattering particles may be provided as light-scattering particles, for example metal oxides, for example silicon oxide (SiO₂), zinc oxide (ZnO), zirconium oxide (ZrO₂), indium tin oxide (ITO) or indium zinc oxide (IZO), gallium oxide (Ga₂Oₐ) aluminum oxide or titanium oxide. Other particles may also be suitable, so long as they have a refractive index which is different to the effective refractive index of the matrix of the translucent layer structure, for example air bubbles, acrylate, or hollow glass spheres. Furthermore, for example, metal nanoparticles, metals such as gold or silver, iron nanoparticles, or the like, may be provided as light-scattering particles.

In various embodiments, an electrically insulating layer (not represented) may also be applied between the second electrode 114 and the layer of adhesive and/or protective coating 124, for example a layer of SiN, for example with a layer thickness in a range of from approximately 300 nm to approximately 1.5 μm, for example with a layer thickness in a range of from approximately 500 nm to approximately 1 μm, in order to protect electrically unstable materials, for example during a wet chemical process.

In various embodiments, the adhesive may be configured so that it itself has a refractive index which is less than the refractive index of the cover 126. Such an adhesive may for example be a low-index adhesive, for example an acrylate, which has a refractive index of approximately 1.3. Furthermore, a plurality of different adhesives, which form an adhesive layer sequence, may be provided.

Furthermore, it should be pointed out that, in various embodiments, an adhesive 124 may even be entirely omitted, for example in embodiments in which the cover 126, for example consisting of glass, is applied for example by plasma spraying onto the encapsulation 108.

In various embodiments, the cover 126 and/or the adhesive 124 may have a refractive index (for example at a wavelength of 633 nm) of 1.55.

Furthermore, in various embodiments one or more antireflection layers (for example combined with the encapsulation 108, for example the thin-film encapsulation 108) may additionally be provided in the light-emitting component 100.

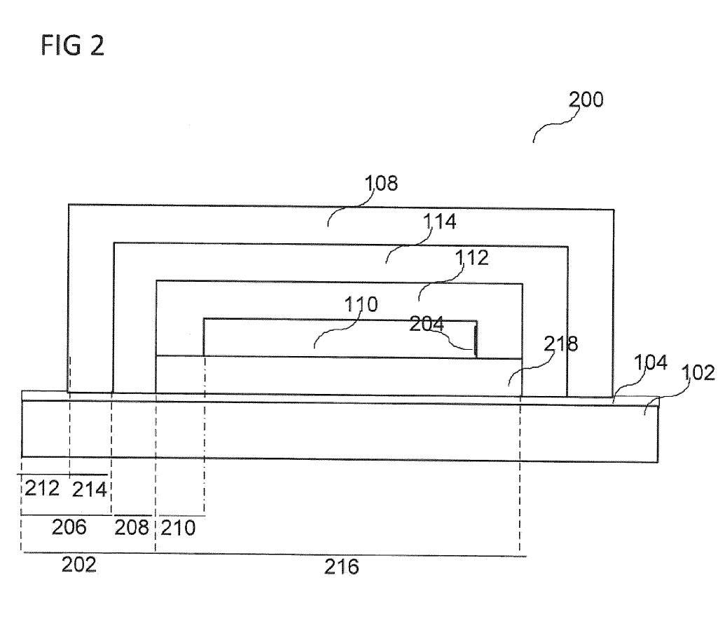

FIG. 2 shows a schematic cross-sectional view of an optoelectronic component according to various embodiments.

A first specific configuration 200 of an optoelectronic component 100 is represented, with the carrier 102, the insulation layer 218, the first electrode 110, the organic functional layer structure 112, the second electrode 114 and the encapsulation 108.

Without restriction of generality, the schematic layer cross section represented for the description of FIG. 2 is assumed to be mirror-symmetrical. For better clarity, the interfaces of individual neighboring layers are presented as projections of the interfaces 202, 206, 208, 210, 212, 214, 216.

Indications relating to the substance composition and thickness of the individual layers represented in FIG. 2 to FIG. 8 are in various embodiments the same as those of the embodiments as described in FIG. 1.

The carrier 102 may have an intrinsic electrical conductivity, for example in a range of from approximately 1 MS/m to approximately 62 MS/m.

The carrier 102 may have a sheet resistance in a range of from approximately 30 μΩ/ to approximately 1Ω/.

The carrier 102 may furthermore be hermetically sealed against water and oxygen, i.e. diffusion of water and/or oxygen through the carrier 102 is not possible.

The carrier 102 may be configured to be flat and mechanically flexible, for example be a metal foil, and a surface area with a size of approximately 1 m×100 m, for example with a size of approximately 0.6 m×0.6 m, for example with a size of approximately 0.2 m×0.2 m, for example with a size of approximately 0.2 m×0.05 m; with a thickness in a range of from approximately 10 μm to approximately 3000 μm, for example in a range of from approximately 20 μm to approximately 1000 μm, for example in a range of from approximately 50 μm to approximately 500 μm.

The at least one electrically insulating region may include the same substance or a similar substance, or the same substance mixture or a similar substance mixture, as the carrier 102 or the insulation layer 218.

The at least one electrically conductive region may include the same substance or a similar substance, or the same substance mixture or a similar substance mixture, as the first electrode 110 or the second electrode 114.

The insulation layer 218 may be applied on the carrier 102 and may electrically insulate the first electrode 110 from the carrier 102 in the region 216.

The insulation layer 218 may reduce the surface roughness of the first electrode 110. In other words: the insulation layer 218 may planarize the surface of the first electrode 110.

The insulation layer 218 may cover surface of the carrier 102 as far as an edge region 202, in which case the edge region 202 may have an extent in a range of from approximately 50 nm to approximately 5 mm, for example in a range of from approximately 5 μm to approximately 2 mm.

The first electrode 110 may cover the insulation layer 218 as a layer as far as an edge region 210, in which case the edge region 210 may have an extent in a range of from approximately 2 μm to approximately 2 mm.

An organic functional layer structure 112 may be applied onto the first electrode 110 in such a way that the organically functional layer structure 112 at least partially encloses the first electrode 110 in the layer cross section, i.e. it covers the edge region 210 of the insulation layer 218 and the first electrode 110 is physically isolated from the second electrode 114.

The side surfaces 204 of the first electrode 110 have physical contact 204 with the organic functional layer structure 112 in the layer cross section 200. The organic functional layer structure 112 may have no direct electrical or physical contact with the carrier 102.

In the layer cross section 200, the first electrode 110 may nevertheless be fully enclosed at least partially by the insulation layer 218 and the organic functional layer structure 112.

The insulation layer 218 may also be made of the same substance or substance mixture, or have the same or a similar layer cross section 112, as the organic functional layer structure 112.

In other words: if an insulation layer 218 with an electrically insulating effect in relation to the carrier 102 is optional, the first electrode 110 may be fully enclosed by the organic functional layer structure 112.

The second electrode 114 may be applied as a layer onto the organic functional layer structure 112. The second electrode 114 may have physical and electrical contact 208 with the carrier 102 in such a way that an edge region 206 of the carrier remains uncovered. The second electrode 114 may in this case enclose the organic functional layer structure 112 and the insulation layer 218 by the physical contact 208.

The second electrode 114 may also include the same substance or the same substance mixture as the carrier 102.

The thin-film encapsulation 108 may be applied onto the second electrode 114, and may enclose or surround the latter. The thin-film encapsulation 108 may in this case be in direct physical contact 214 with the carrier, and thus hermetically encapsulate the layers between the encapsulation 108 and the carrier 102 against water and oxygen, i.e. diffusion through the thin-film encapsulation 108 may not be possible. In other words: by the direct physical contact 214, the entire interface of the thin-film encapsulation 108 with the carrier 102 may be hermetically sealed against harmful environmental effects.

The edge region 212 of the carrier 102 may be configured with a thickness in a range of from 0 mm to approximately 10 mm, for example from approximately 0.1 mm to approximately 2 mm, for example approximately 1 mm, an extent of 0 mm corresponding to the absence of the edge region 212.

Furthermore represented is a barrier thin film 104 on or over the carrier 102, for example according to a configuration of the description of FIG. 1.

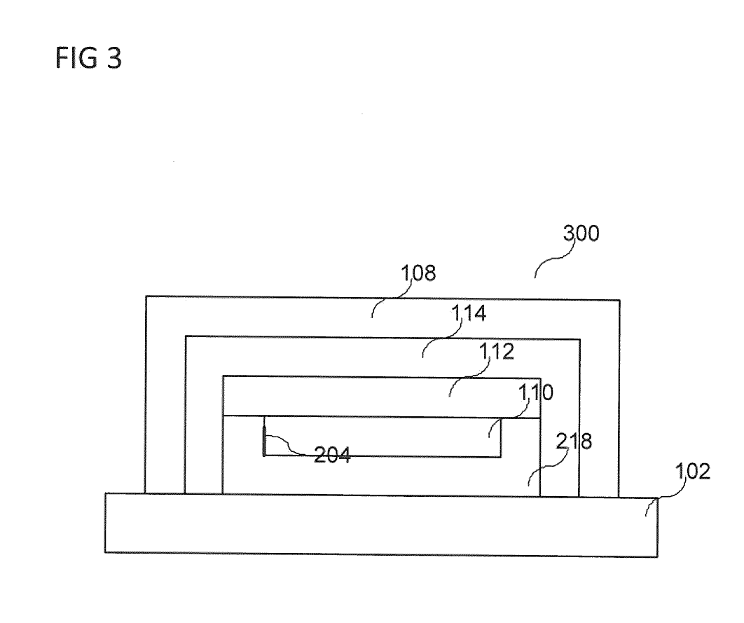

The barrier thin film 104 may be applied on or over the carrier 102 in various configurations of the description of FIG. 3 to FIG. 8, even if the barrier thin film 104 is not explicitly represented or explicitly described.

FIG. 3 shows a schematic cross-sectional view of an optoelectronic component according to various embodiments.

FIG. 3 differs from the embodiments in FIG. 2 in that the insulation layer 218, on which the first electrode 110 is applied, laterally encloses the first electrode 110, i.e. the contact 204 may also be formed between the insulation layer 218 and the first electrode 110.

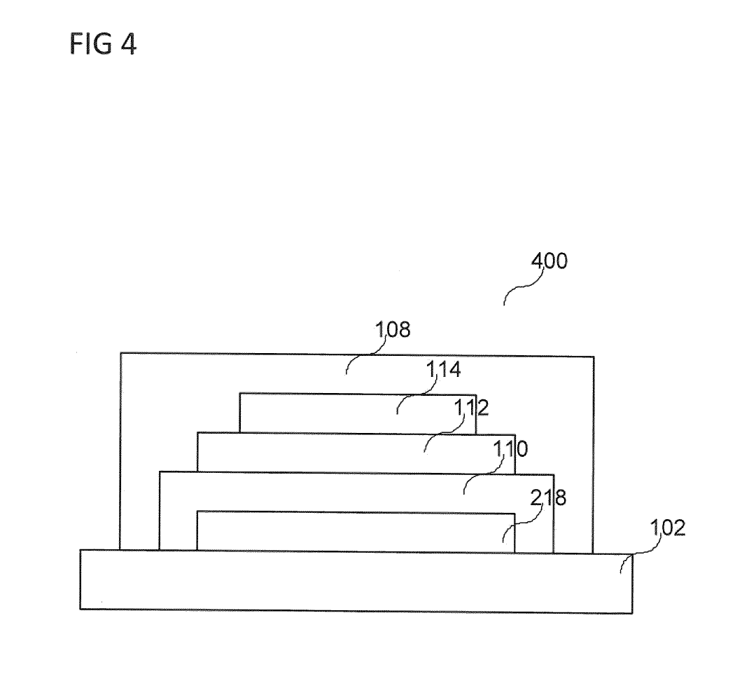

FIG. 4 shows a schematic cross-sectional view of an optoelectronic component according to various embodiments.

In contrast to FIG. 2 and FIG. 3, the first electrode 110 may also be electrically connected to the carrier 102, as can be seen in the embodiments in FIG. 4.

The first electrode 110 may enclose or surround the insulation layer 218. The organically functional layer structure 112 physically isolates the second electrode 114 from the first electrode 114, i.e. the second electrode 114 should not extend beyond the organic functional layer structure 112 in terms of area and therefore form an electrical contact with the first electrode 110. The thin-film encapsulation 108 may hermetically encapsulate the layers in the layer cross section 400 against water and/or oxygen in conjunction with the carrier 102 in the space between the thin-film encapsulation 108 and the carrier 102.

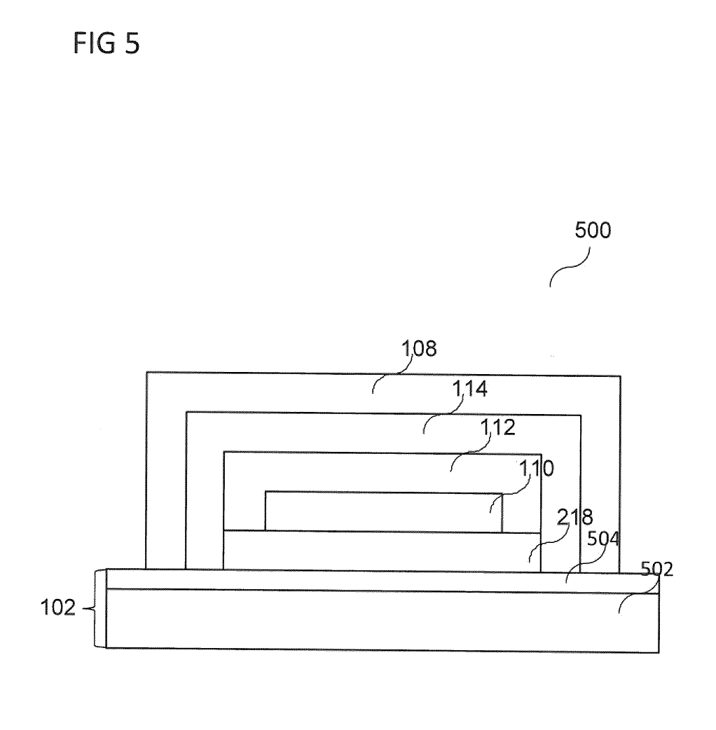

FIG. 5 shows a schematic cross-sectional view of an optoelectronic component according to various embodiments.

FIG. 5 represents a layer sequence similar to FIG. 2 in the layer cross section 500. The carrier 102 may include an electrically insulating region and an electrically conductive region, for example an electrically insulating region 502 with an electrically conductive region 504, for example an electrically conductive conductor layer 504.

The at least one electrically insulating region may include the same substance or a similar substance, or the same substance mixture or a similar substance mixture, as the carrier 102 or the insulation layer 218.

The at least one electrically conductive region may include the same substance or a similar substance, or the same substance mixture or a similar substance mixture, as the first electrode 110 or the second electrode 114.

The conductor layer 504 may be necessary if the carrier 502 itself is not electrically conductive or has an insufficient electrical conductivity.

The conductor layer 504 may include the same substance or a similar substance, or the same substance mixture or a similar substance mixture, as the first electrode 110 or the second electrode 114.

With an electrically insulated system carrier 502, for example, a leakage current can be reduced or avoided.

In other words: with an electrically insulated system carrier 502, electrical insulation from the environment can be provided.

An electrically insulated system carrier 502 may, for example, also be configured as mechanical protection and/or for mechanical stabilization of the conductor layer 504.

For electrical contacting of the optoelectronic component 100, therefore, the conductive layer 504 may be applied onto the carrier 502.

In order to form a hermetically sealed carrier 102, the electrically conductive layer may be formed with a thickness of approximately thicker than approximately 5 μm, for example a copper layer with a thickness in a range of from approximately 5 μm to approximately 200 μm, for example 30 μm.

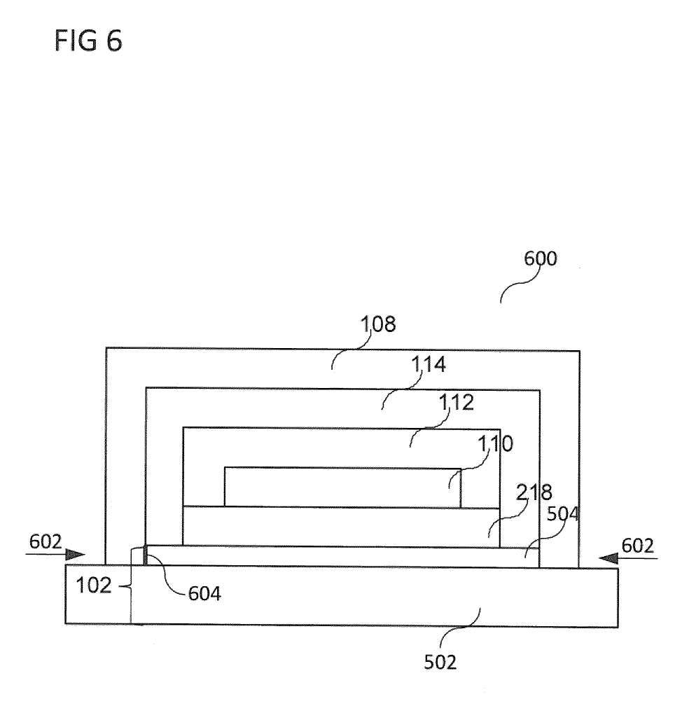

FIG. 6 shows a schematic cross-sectional view of an optoelectronic component according to various embodiments.

FIG. 6 represents a layer sequence similar to FIG. 5 in layer cross section.

In order to reduce diffusion flows of harmful environmental effects, for example harmful substances, for example water and/or oxygen, for example through the sides of the electrically conductive layer 504, or its physical contacts with neighboring layers (diffusion flows are indicated by arrows 602), the thin-film encapsulation 108 may enclose the sides 604 of the insulation layer 218 and/or of the conductive layer 504.

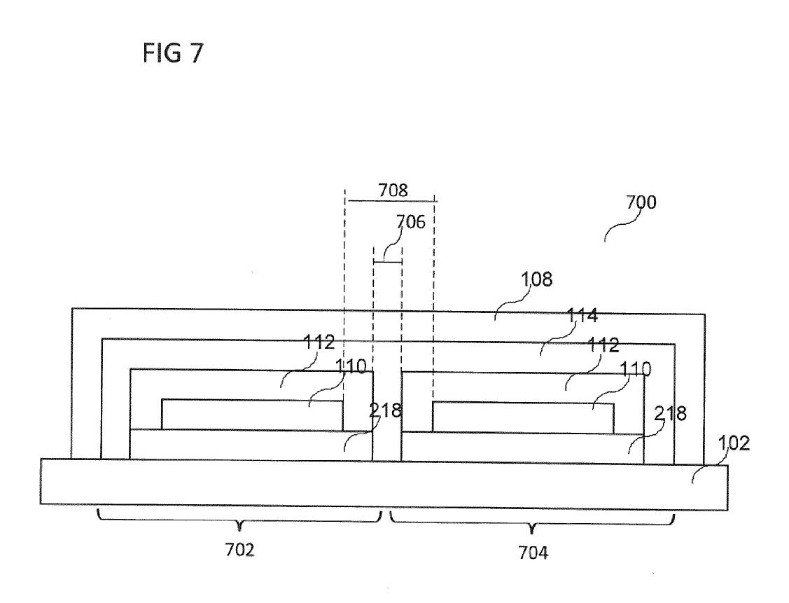

FIG. 7 shows a schematic cross-sectional view of two optoelectronic components 702, 704 according to various embodiments.

FIG. 7 represents in layer cross section a layer sequence similar to FIG. 2 or FIG. 5 with two or more optoelectronic components 702, 704 enclosed by encapsulation 108.

The carrier 102 may in this case have an intrinsic conductivity (FIG. 2) or an insulating region with a conductive region (FIG. 5).

The first optoelectronic component 702 and the second optoelectronic component 704 may, for example, be arranged next to one another and have a common electrode, for example a common second electrode 114.

The second electrode 114 may enclose the insulation layer 218 and the organic functional layer structure 112 of the first optoelectronic component 702 and of the second optoelectronic component 704.

An electrical contact 706 of the second electrode 114 with the carrier 102 may be formed between the optoelectronic components 702, 704, for example for parallel current conduction over the substrate with a high conductance and therefore a low voltage drop.

By the electrical contact 706, the flow of current from the carrier 102 through the flat side of the second electrode 114 can be reinforced, since the carrier 102 can have a higher electrical conductivity and/or a lower sheet resistance than the second electrode 114.

In the region of the electrical contact 706 of the common electrode 114, current transport may be formed next to, for example perpendicularly to, the flat surface of the second electrode 114.

By the electrical contact 706 of the common first electrode 110 (not represented) and/or of the common second electrode 114 (represented) of the plurality of optoelectronic components 702, 704 with the common carrier 102, the contact area of one of the common electrodes 110, 114 with the electrically conductive carrier 102 can be reduced.

The electrical contact 706 may have a width in a range of from approximately 10 nm to approximately 1 cm, for example in a range of from approximately 200 nm to approximately 2 mm, for example in a range of from approximately 10 μm to approximately 500 μm. The distance 706 between the first electrodes 110 between the two optoelectronic components 702, 704 may include a width in a range of from approximately 10 nm to approximately 1 cm, for example in a range of from approximately 200 nm to approximately 2 mm, for example in a range of from approximately 10 μm to approximately 500 μm.

The electrical contact 706 may be configured to be lengthened in the plane of the drawing, i.e. perpendicularly in both directions to the section plane represented, continuously, for example uninterruptedly, or interrupted.

An interruption of the electrical contact 706 in the plane of the drawing may, for example, be formed by a connection of the insulation layers 218 of the two optoelectronic components 702, 704 in the region of the electrical contact 706, or a common insulation layer 218 of the two optoelectronic components 702, 704, with a vertical interruption of the through-contact, for example a VIA.

The width of the distance 706 between the two optoelectronic components 702, 704 may be configured in such a way that the separation 706 in the radiating and/or non-radiating state of the components is not perceptible, or is scarcely perceptible, to the human eye.

The visible non-radiating region between the two optoelectronic components 702, 704 may have a width in a range of approximately between the size of the distance 706 and the size of the distance 708.

The encapsulation 108 with the carrier 102 may enclose the second electrode 114, for example enclosing it continuously without gaps.

The optoelectronic components 702, 704 may have the same layer cross section 100 or a different layer cross section 100 in relation to the thickness and the substance composition of the individual layers of the layer structure 100.

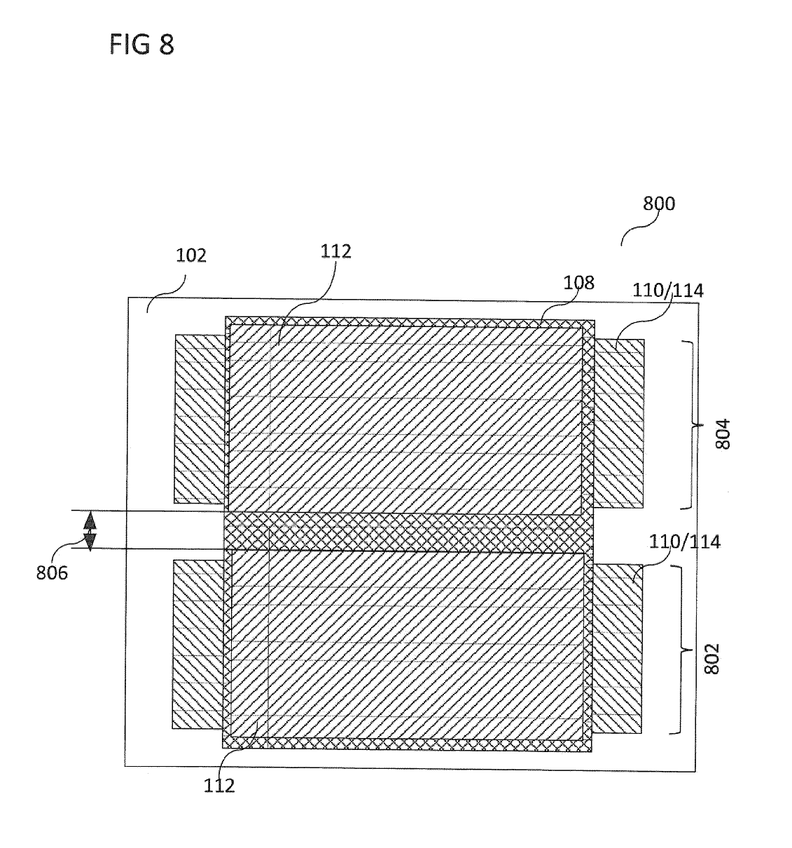

FIG. 8 shows a schematic plan view of an optoelectronic component according to various embodiments.

FIG. 8 represents in plan view 800 a plurality of optoelectronic components 802, 804, for example similar or identical to one of the configurations of the description of FIG. 7, for example similar or identical to a combination of two or more optoelectronic components with the same or a different configuration of the descriptions of FIG. 2 to FIG. 6, for example two optoelectronic components with a configuration of the description of FIG. 2.

The carrier 102 and the encapsulation 108 are represented, which together enclose at least the organic functional layer structure 112 and the (optional) insulation layer 218 continuously without gaps.

The electrical feed of the first electrode 110, or of the second electrode 114, through the encapsulation 108 is furthermore represented.

The (very small) distance 806 between the organic functional layer structures 112 of the optoelectronic components 802, 804 is furthermore represented.

The width of the distance 806 may be given by the widths of the electrical connection widths, in the configuration of FIG. 2 for example the distance 208, and the contact area of the thin-film encapsulation 108 with the carrier 102, in the configuration of FIG. 2 for example the distance 214, of the optoelectronic components 802, 804.

In various embodiments, a component is provided, the component including: a carrier; a first electrode on or over the carrier; an organic functional layer structure on or over the first electrode; a second electrode on or over the organic functional layer structure, wherein the first electrode and the second electrode are configured in such a way that an electrical connection of the first electrode to the second electrode is established only through the organic functional layer structure; and a self-supporting cover; wherein the first electrode and/or the second electrode is electrically coupled to the carrier; and wherein the cover together with the carrier forms a structure which seals the organic functional layer structure as well as at least one electrode out of the first electrode and the second electrode hermetically against water and/or oxygen, wherein the region between the carrier and the cover is laterally sealed hermetically by a structure containing metal.

A self-supporting cover is a cover which does not require a substrate or carrier in order to be able to maintain the structural integrity of the cover.

The structure containing metal may, for example, include a metal and/or a metal oxide. The structure containing metal may, for example, include or be formed from a metal according to one of the configurations of the first electrode or second electrode.

The structure containing metal may be applied or formed laterally, i.e. on the side, on the region between the cover and the carrier.

The structure containing metal may be arranged or formed on the side of the optoelectronic component and/or on the side, facing away from the optoelectronic component, of the region between the carrier and the cover. For example, the structure containing metal may be formed between the cover and the carrier as an indirect connection of the carrier and the cover, for example in the edge region of the component.

The structure containing metal may be electrically connected to one of the electrodes of the component and/or electrically insulated from at least one. For example, the structure containing metal may be connected to one of the electrodes of the component in at least one region and electrically insulated from one of the electrodes of the component in at least one region. For example, the structure containing metal may have no electrical connection with one of the electrodes in at least one.

The structure containing metal may be configured for atomic connection of the cover to the carrier, for example as an adhesive or solder; and/or seal the region between the carrier and the cover in a hermetically sealed way against water and/or oxygen.

The structure containing metal may—depending on the specific configuration of the structure containing metal—be sprayed, vapor-deposited; applied in a solution, paste, dispersion or emulsion.

In various embodiments, components and a method for their production are provided, with which it is possible to produce arbitrarily thick organic optoelectronic components which can be processed very well and are hermetically sealed, and which have a larger active area on a carrier than conventional optoelectronic components. In this way organic optoelectronic components can be contacted over an area, so that in the case of radiation-emitting components the overall appearance is not impaired and in the case of radiation-absorbing components the radiation-absorbing area is increased. At the same time, contacts, for example VIAs, through the encapsulation can be obviated, or their number can be reduced. In this way, potential diffusion flows of water and/or oxygen through the encapsulation can be prevented or reduced.

While the disclosed embodiments have been particularly shown and described with reference to specific embodiments, it should be understood by those skilled in the art that various changes in form and detail may be made therein without departing from the spirit and scope of the disclosed embodiments as defined by the appended claims. The scope of the disclosed embodiments is thus indicated by the appended claims and all changes which come within the meaning and range of equivalency of the claims are therefore intended to be embraced.

1. A component, comprising:
a carrier;
a first electrode on or over the carrier;
an organic functional layer structure on or over the first electrode;
a second electrode on or over the organic functional layer structure, wherein the first electrode and the second electrode are configured in such a way that an electrical connection of the first electrode to the second electrode is established only through the organic functional layer structure; and
thin-film encapsulation;
wherein the first electrode and/or the second electrode is electrically coupled to the carrier; and
wherein the thin-film encapsulation together with the carrier forms a structure which seals the organic functional layer structure as well as at least one electrode out of the first electrode and the second electrode hermetically against water and/or oxygen.

2. The component as claimed in claim 1, wherein the carrier is configured to be electrically conductive.

3. The component as claimed in claim 1, wherein the carrier comprises at least one electrically insulating region and at least one electrically conductive region.

4. The component as claimed in claim 3, wherein the electrically conductive region is configured as a conductor layer on the electrically insulating region.

5. The component as claimed in claim 1,
wherein an insulation layer is formed between the first electrode and the carrier.

6. The component as claimed in claim 5, wherein the insulation layer is configured to be transparent or translucent.

7. The component as claimed in claim 5,
wherein the thin-film encapsulation encloses with the carrier a plurality of layer structures in such a way that the individual layer structures comprise the layers: an insulation layer, a first electrode, an organic functional layer structure and a second electrode;
wherein the plurality of layer structures are configured in such a way that the plurality of layer structures have a common first electrode and/or a common second electrode.

8. The component as claimed in claim 7, wherein the common first electrode and/or the common second electrode has an electrical contact with the common carrier between the plurality of layer structures.

9. The component as claimed in claim 1,
wherein the first electrode is configured to be transparent.

10. The component as claimed in claim 1,
wherein the second electrode is configured to be transparent.

11. The component as claimed in claim 1,
wherein the organic functional layer structure encloses the first electrode in such a way that the organic functional layer structure physically isolates the first electrode laterally from the second electrode.

12. The component as claimed in claim 1,
wherein the component is configured as an optoelectronic component.

13. A method for producing a component, the method comprising:
forming a first electrode over or on a carrier;
forming_an organic functional layer structure over or on the first electrode;
forming a second electrode over or on the organic functional layer structure; and
forming thin-film encapsulation;
wherein
the first electrode and the second electrode are configured in such a way that an electrical connection of the first electrode to the second electrode is established only through the organic functional layer structure;
the first electrode or the second electrode is configured to be electrically coupled to the carrier; and
wherein the thin-film encapsulation together with the carrier forms a structure which seals the organic functional layer structure as well as at least one electrode out of the first electrode and the second electrode hermetically against harmful environmental effects.

14. The method as claimed in claim 13,
wherein an insulation layer is applied on or over the carrier before the first electrode is applied on the carrier.

15. The method as claimed in claim 13, wherein the thin-film encapsulation is formed on or over the carrier in such a way that the thin-film encapsulation encloses a plurality of layer structures on a common carrier, wherein the individual layer structures comprise the layers: an insulation layer; a first electrode; an organic functional layer structure; and a second electrode.

16. The method as claimed in claim 15, wherein the plurality of layer structures are configured in such a way that the plurality of layer structures have a common first electrode and/or a common second electrode.

17. The method as claimed in claim 16, wherein the common first electrode and/or the common second electrode is/are formed with electrical contact with the common carrier between the plurality of layer structures.

18. A component, comprising:
a carrier;
a first electrode on or over the carrier;
an organic functional layer structure on or over the first electrode;
a second electrode on or over the organic functional layer structure, wherein the first electrode and the second electrode are configured in such a way that an electrical connection of the first electrode to the second electrode is established only through the organic functional layer structure; and
a self-supporting cover;
wherein the first electrode and/or the second electrode is electrically coupled to the carrier; and
wherein the cover together with the carrier forms a structure which seals the organic functional layer structure as well as at least one electrode out of the first electrode and the second electrode hermetically against water and/or oxygen, wherein the region between the carrier and the cover is laterally sealed hermetically by a structure containing metal.

19. The component as claimed in claim 1, wherein the component is configured as an organic light-emitting diode or as an organic solar cell.
